(19) United States
(12) Patent Application Publication
(10) Pub. No.: US 2011/0024764 A1
(43) Pub. Date: Feb. 3, 2011

(54) SEMICONDUCTOR DEVICE, METHOD FOR PRODUCING THE SAME, AND DISPLAY DEVICE

(76) Inventor: Tomohiro Kimura, Osaka (JP)

Correspondence Address: BIRCH STEWART KOLASCH & BIRCH, PO BOX 747, FALLS CHURCH, VA, 22040-0747, US

(21) Appl. No.: 12/921,666

(22) PCT Filed: Oct. 31, 2008
(86) PCT No.: PCT/JP2008/069933

§ 371 Date: Sep. 9, 2010

(30) Foreign Application Priority Data
Mar. 31, 2008 (JP) 2008-092871

(51) Int. Cl. H01L 29/04; H01L 27/12; H01L 21/336

(52) U.S. Cl. 257/72; 257/347; 438/591; 257/E27.111; 257/E21.409; 257/E29.003

(57) ABSTRACT

The present invention provides a semiconductor device which can reduce Iₒₙ defects due to reduction in an on-current. A semiconductor device of the present invention comprises: a substrate; a thin film transistor including a crystalline semiconductor layer which has a channel region and a source/drain region; and a wiring connected to the source/drain region. The thin film transistor and the wiring are disposed on the substrate. The crystalline semiconductor layer further has a low-impurity-concentration region which has a lower impurity concentration than that of the source/drain region and a contacting portion contacting with the wiring. The low-impurity-concentration region is disposed adjacent to the source/drain region except a region on a channel-region side of the source/drain region.

### TECHNICAL FIELD

The present invention relates to a semiconductor device, a method for producing the same, and a display device. The present invention specifically relates to a semiconductor device suitable for medium- and small-sized display devices for mobile phones, digital cameras, vehicle-mounted devices, and the like devices, a method for producing the same, and a display device.

### BACKGROUND ART

Semiconductor devices are electronic devices provided with active elements utilizing electrical characteristics of semiconductors. They are widely used in various devices such as audio devices, communication devices, computers, and home appliances. In particular, semiconductor devices provided with thin film transistors (TFT) are widely used in components such as pixel-switching elements and driver circuits of active-matrix liquid crystal display devices.

In the current mobile display device (display) industry, higher-performance TFTs are greatly required in accordance with an increase in a demand for improved properties such as lower power consumption, greater multi-functionality, more rapid operation, higher reliability, higher definition, and much miniaturization. In order to achieve these improvements, research and development are actively carried out. Silicon used for semiconductor layers of TFTs are classified, depending on crystallinity, into non-crystalline silicon (amorphous silicon) which has lower crystallinity and polycrystalline silicon (polysilicon) which has higher crystallinity. Amorphous silicon is inexpensive and is easily deposited even on non-crystalline materials and materials which are non-resistant to high temperatures, but has low mobility. In contrast, highly crystalline silicon has higher mobility than amorphous silicon by about two orders of magnitude. Thus, use of highly crystalline silicon for semiconductor layers enables improvement in performance of TFTs such as operating speed.

The TFTs including highly crystalline silicon suffer a large leakage current between source/drain regions and are required to be improved in this respect, despite excellent mobility. In order to solve this problem, there is disclosed a technique of reducing a leakage current by formation of a lightly doped drain (LDD) region, which is a low-impurity-concentration region, between a source/drain region and a channel region (see Patent Document 1, for example).

Patent Document 1: Japanese Kokai Publication H08-167722

### DISCLOSURE OF THE INVENTION

In production of TFTs, a source/drain region is formed by ion implantation of impurities at a high dose into a semiconductor layer and activation of the implanted impurities by heat or other factors. The activation causes restoration of the crystalline structure of the source/drain region damaged by the ion implantation; however, the crystalline structure of the source/drain region is insufficiently restored by the activation in the case that an unexpectedly excessive amount of the impurities is ion-implanted or the activation is non-uniformly performed due to non-uniformity in the amount of the implanted impurities, in the accelerating voltage upon the ion implantation, in the thickness of the ion-implanted semiconductor layer or the insulator formed on the semiconductor layer, and the like. Such insufficient crystal restoration of the source/drain region causes an increase in the sheet resistance of the source/drain region, and thus causes an increase in the contact resistance between the source/drain region and a wiring. As a result, the on-resistance of the semiconductor device increases and defects due to reduction in the on-current (hereinafter, also referred to as “Iₒₙ defects”) are caused in some cases.

The present invention is devised in order to solve the aforementioned problems. Objects of the present invention are to provide a semiconductor device which can reduce Iₒₙ defects due to reduction in the on-current; a method for producing the same; and a display device.

The present inventors have performed various studies on the semiconductor device which inhibits Iₒₙ defects due to reduction in the on-current; the method for producing the same; and the display device. Thus, the present inventors have focused on the starting point of the crystal restoration in the source/drain region upon activation. As a result, the present inventors have first found the following respects about the conventional semiconductor devices.

If a region where the crystalline structure is less damaged (a region with high crystallinity) exists in the source/drain region, the crystal restoration upon activation generally starts from this region. The higher the crystallinity of this starting-point region is, the higher the activation efficiency is. In the case that impurities are ion-implanted at a high dose, activation efficiency can be increased and thus the crystal restoration can be efficiently promoted by adjusting the accelerating voltage to make the amount of impurity ions reaching the semiconductor layer on the substrate side as small as possible and thus to form a region where the crystalline structure is less damaged on the semiconductor layer on the substrate side.

Here is described, referring to a drawing, a state of a source/drain region upon ion implantation of impurities at a high dose and activation of the impurities in the case that the depth-profile peak of the ion-implanted impurities is set to be in the gate insulator in the step of forming the source/drain region of a conventional semiconductor device.

FIGS. 8 each are a schematic cross-sectional view showing a source/drain region and its vicinity of a TFT disposed on a conventional semiconductor device; FIG. 8(a) shows a state of the region and its vicinity upon ion implantation of impurities at a high dose; and FIG. 8(b) shows a state of the region and its vicinity upon activation.

As shown in FIG. 8(a), ion implantation is performed on a crystalline semiconductor layer 2 except the region covered with a gate electrode 4 in the conventional semiconductor device by ion implantation of impurities 9 at a high dose into the crystalline semiconductor layer 2 on a substrate 1 through a gate insulator 3. That is, the ion implantation is not performed toward a channel region 5 below the gate electrode 4, but is performed toward the region to be a source/drain region 6 in the crystalline semiconductor layer 2. In FIG. 8(a), the difference in tones corresponds to the difference in crystallinity. A darker portion indicates a region where the crystalline structure is more damaged and the crystallinity is lowered. As the peak of the depth profile 12 of the ion-implanted impurities is set to be in the gate insulator 3, the degree of crystal destruction in the source/drain region 6 gradually increases from the side of the substrate 1 to the side of the gate insulator 3. In other words, the crystalline structure is most greatly damaged at the region adjacent to the gate insulator 3 in the source/drain region 6 and the crystallinity is lowest at this region; while the crystalline structure is less damaged at the region adjacent to the substrate 1 in the source/drain region 6 and the crystallinity is higher at this region.

The crystalline structure of the source/drain region 6 is restored when the impurities 9 ion-implanted into the source/drain region 6 are activated by heat or other factors. In general, the crystal restoration starts from a region with high crystallinity. In the conventional semiconductor device shown in FIG. 8(b), the region adjacent to the substrate 1 in the source/drain region 6 mainly serves as the starting point of the crystal restoration, and the crystal restoration progresses in the direction indicated by the arrow outline. If the crystalline structure of the crystalline semiconductor layer 2 has been greatly damaged due to factors such as non-uniformity in the amount of the ion-implanted impurities, the crystalline structure of the source/drain region 6 is insufficiently restored and the sheet resistance of the source/drain region 6 increases. In addition, the increase in the sheet resistance causes an increase in the contact resistance between the source/drain region 6 and a wiring 10. As a result, the on-resistance of the semiconductor device increases and Iₒₙ defects are caused due to reduction in the on-current.

Thus, the present inventors have performed further studies, and found that the crystal restoration, which has insufficiently progressed in some conventional cases, is presumably promoted by disposing a highly-crystalline low-impurity-concentration region adjacent to the source/drain region as the additional starting point of the crystal restoration upon activation.

Here is described, referring to a drawing, the test results the present inventors have obtained from the test performed in order to examine the effect of the crystal restoration in the source/drain region adjacent to the low-impurity-concentration region upon activation.

In the test, the present inventors prepared a polysilicon in which an excessive amount of impurities were ion-implanted so that the crystalline structure was insufficiently restored upon activation. The states of the prepared polysilicon before and after activation were observed with an optical microscope and were analyzed by the Raman spectrum measurement.

FIG. 9(a) is an optical micrograph of the polysilicon before activation; and FIG. 9(b) is a graph showing the Raman spectrum of the polysilicon before activation. For the comparison purpose, amorphous silicon not subjected to the ion implantation and activation was also examined. FIG. 11(a) is an optical micrograph of the amorphous silicon; and FIG. 11(b) is a graph showing the Raman spectrum of the amorphous silicon.

As shown in FIG. 9(a), impurities were ion-implanted at a high dose into a polysilicon 20, and thus an ion-implanted region 21 was formed in the about 20-μm square indicated by a dot line. The ion-implanted region 21 corresponds to the source/drain region of the semiconductor device where the crystalline structure is greatly damaged. In this case, the region surrounding the ion-implanted region 21 was regarded as a non-implanted region 17 where the ion implantation was not performed.

With respect to such a polysilicon 20, the point P in FIG. 9(a), substantially the center of the ion-implanted region 21, and the point L, in the non-implanted region 17, were analyzed by Raman spectroscopy. The results were compared with those obtained from the amorphous silicon 23 shown in FIG. 11(b). As shown in FIG. 9(b), the Raman spectrum at the point Q gives a pattern in which the peak of the highly crystalline silicon is around 520 cm⁻¹, while the Raman spectrum at the point P gives a broad pattern similar to the Raman spectrum of the amorphous silicon 23 shown in FIG. 11(b). Thus, the present inventors have found that the crystalline structure was damaged at the ion-implanted region 21 where the impurities were ion-implanted at a high dose.

FIG. 10(a) is an optical micrograph of the polysilicon after activation; and FIG. 10(b) is a graph showing the Raman spectrum of the polysilicon after activation. As shown in FIG. 10(a), a dark region in the ion-implanted region 21 was narrowed at the region adjacent to the non-implanted region 17 of the ion-implanted region 21 in the polysilicon 20 after activation.

The point P, substantially the center of the ion-implanted region 21, the point S, disposed within the ion-implanted region 21 and apart from the non-implanted region 17 by about 2 μm, and the point R, the middle of the points P and S, were analyzed by Raman spectroscopy. As shown in FIG. 10(b), the Raman spectra at the points P and R each give a broad pattern similar to the Raman spectrum of the amorphous silicon 23 in FIG. 11(b) with a peak of highly crystalline silicon around 520 cm⁻¹; while the Raman spectrum at the point S indicates a peak of highly crystalline silicon around 520 cm⁻¹, which is similar to the Raman spectrum at the point Q in FIG. 9(b). Thus, the present inventors have found that the crystallinity at the point S, disposed on the ion-implanted region 21 and apart from the non-implanted region 17 by about 2 μm, was restored by activation to the similar level of the crystallinity at the non-implanted region 17.

From the above results, the present inventors have found that the crystal restoration in the source/drain region, which has been insufficient in some cases, is sufficiently promoted by disposing the low-impurity-concentration region adjacent to the source/drain region as the additional starting point of the crystal restoration. Thus, the present inventors have arrived at the present invention which solves the aforementioned problems.

One aspect of the present invention is a semiconductor device comprising: a substrate; a thin film transistor including a crystalline semiconductor layer which has a channel region and a source/drain region; and a wiring connected to the source/drain region, the thin film transistor and the wiring being disposed on the substrate, the crystalline semiconductor layer further having a low-impurity-concentration region which has a lower impurity concentration than that of the source/drain region and a contacting portion contacting with the wiring, and the low-impurity-concentration region being disposed adjacent to the source/drain region except a region on a channel-region side of the source/drain region.

The crystal restoration in the source/drain region occurs upon activation regardless of the presence of a gradient of crystal destruction (crystal defects). If a region where the crystal structure is less damaged exists, the crystal restoration is promoted starting from this region. In this case, the less the crystal structure is damaged at the starting-point region, the more the crystal restoration is promoted upon activation. That is, the present invention causes the crystal restoration in the source/drain region upon activation to start from not only a region where the crystalline structure is less damaged within the source/drain region (for example, the substrate side in the source/drain region), but also the low-impurity-concentration region adjacent to the source/drain region. Thus, the crystal restoration in the source/drain region can be greatly promoted in comparison with conventional cases. As a result, the crystal restoration can be sufficiently progress in the source/drain region upon activation, the sheet resistance at the source/drain region can be reduced, the contact resistance between the source/drain region and the wiring can be reduced, the on-resistance of the semiconductor device can be reduced, and Iₒₙ defects due to reduction in the on-current can be reduced. In addition, the reduction in the contact resistance between the source/drain region and the wiring can lead to reduction in contact failures.

The source/drain region herein represents a region serving as a source and/or drain of a TFT. The thin film transistor (crystalline semiconductor layer) is generally provided with two source/drain regions disposed on opposite sides of the channel region; one serves as the source and the other serves as the drain. The low-impurity-concentration region is disposed adjacent to the source/drain region except the channel-region side of the source/drain region, and thus it is distinguished from the LDD region by their locations.

The configuration of the semiconductor device of the present invention is not especially limited as long as it essentially includes such components. The semiconductor device may or may not include other components.

Preferable embodiments of the semiconductor device of the present invention are mentioned in more detail below. The following embodiments may be employed in combination.

The low-impurity-concentration region is a region where impurities are not ion-implanted at a dose as high as in the source/drain region. Impurities may be implanted at a low dose into the region, or the region may be a non-implanted region where impurities are not implanted. Specifically, the low-impurity-concentration region preferably has an impurity concentration of 50% or less (more preferably 10% or less) of that in the source/drain region. Such an impurity concentration can cause higher crystallinity of the low-impurity-concentration region and further promotes the crystal restoration in the source/drain region starting from the low-impurity-concentration region. If the impurity concentration is higher than 50% in the low-impurity-concentration region, the low-impurity-concentration region may not sufficiently serve as the starting point of the crystal restoration.

The low-impurity-concentration region is preferably disposed on the same plane of the source/drain region, although it may be disposed above or below the source/drain region (disposed on a different plane in the thickness direction) if possible. In this case, the low-impurity-concentration region can be easily formed with a photoresist or the like members.

The contacting portion may partially overlap the low-impurity-concentration region. In this case, the source/drain region in which the crystal restoration occurs adjacent to the low-impurity-concentration region can be surely disposed toward the contacting portion. Thus, the contact resistance can be surely reduced, and contact failures and Iₒₙ defects can be surely reduced.

The low-impurity-concentration region may be disposed along the perimeter of the contacting portion except the channel region side of the perimeter in the plan view of the substrate. In this case, the crystal restoration in the source/drain region can be efficiently promoted around the contacting portion. Thus, the contact resistance can be further reduced, and contact failures and Iₒₙ defects can be further reduced. In order to achieve the same effects, the low-impurity-concentration region may be disposed so as to have a shape with a depression (e.g. a U shape) in the plan view of the substrate, and the depression may be disposed along the perimeter of the contacting portion.

The low-impurity-concentration region may be disposed along a current path between the contacting portion and the channel region in the plan view of the substrate. In this case, the crystal restoration in the source/drain region can be promoted around the current path between the contacting portion and the channel region. Thus, the sheet resistance of the source/drain region through which the current path runs between the contacting portion and the channel region can be reduced and the on-resistance of the semiconductor device can be further reduced. As a result, Iₒₙ defects can be further reduced.

The thin film transistor is generally provided with two contacting portions disposed on the opposite sides of the channel region, and a current (on-current) passes through between the two contacting portions. In other words, the current path is disposed between the two contacting portions. Thus, in order to achieve the same effects as those of the above mode, the crystalline semiconductor layer may include at least two contacting portions disposed on the opposite sides of the channel region, and the low-impurity-concentration region may be disposed along the region between the contacting portions disposed on the opposite sides of the channel region in the plan view of the substrate.

The low-impurity-concentration region may be disposed along the current path between the contacting portion and the channel region, and also along the perimeter of the contacting portion except the channel-region side of the perimeter in the plan view of the substrate. In this case, the crystal restoration in the source/drain region can be promoted around the current path between the contacting portion and the channel region. Thus, the sheet resistance of the source/drain region through which the current path runs between the contacting portion and the channel region can be reduced. In addition, the crystal restoration in the source/drain region can be efficiently promoted around the contacting portion. Thus, the contact resistance can be further reduced.

As a result, the on-resistance of the semiconductor device can be further reduced and Iₒₙ defects can be further reduced. In addition, contact failures can be further reduced because the contact resistance can be reduced.

Similar to the aforementioned case, the crystalline semiconductor layer may be provided with at least two contacting portions disposed on the opposite sides of the channel region, and the low-impurity-concentration region may be disposed along the region between the contacting portions disposed on the opposite sides of the channel region and also along the perimeter of the contacting portions except the channel-region side of the perimeter in the plan view of the substrate.

The semiconductor device may include a resist on a gate insulator at the region covering the low-impurity-concentration region. That is, the thin film transistor may include a gate insulator, and the semiconductor device may include a resist disposed on the gate insulator and covering the low-impurity-concentration region. In this case, the low-impurity-concentration region can be easily formed in the crystalline semiconductor layer at the region masked by the resist. In addition, the region masked by the resist can be located. Thus, the properties such as a shape of the low-impurity-concentration region, the alignment accuracy, and the like factors can be easily tested and analyzed.

The resist may be a residual resist after resist removal in the production procedure, namely the resist residue. The degree of the resist remaining (e.g. the thickness of the resist residue) can be controlled generally by appropriate choice of factors such as a resist material and a removing method.

In the gate insulator, the region covering the low-impurity-concentration region may be integrated with the region covering the source/drain region. In addition, at least one of the thickness and quality of the gate insulator at the region covering the low-impurity-concentration may be different from those at the region covering the source/drain region. That is, the thin film transistor may include the gate insulator, and the region covering the low-impurity-concentration region may be integrated with the region covering the source/drain region in the gate insulator, as well as at least one of the thickness and quality of the gate insulator at the region covering the low-impurity-concentration may be different from those at the region covering the source/drain region. In this case, the concentration of impurities implanted into the crystalline semiconductor layer can be adjusted by use of at least one of the non-uniform thickness and quality of the integrated gate insulator. Thus, the low-impurity-concentration region can be easily formed in the crystalline semiconductor layer at the region covered with the region where at least one of the thickness and quality is different from those at the other region of the gate insulator.

In one example that the quality of the insulator is different, the region covering the low-impurity-concentration region is denser (for example, structure defects less occur) than the region covering the source/drain region in the gate insulator. Such a structure can be formed owing to variations in the film-forming conditions between the regions, such as temperature, gas-flow amount, and applied voltage.

The gate insulator may include a multilayer insulator at the region covering the low-impurity-concentration region. That is, the thin film transistor may include the gate insulator, and the gate insulator may include the multilayer insulator at the region covering the low-impurity-concentration region. In this case, the gate insulator is allowed to easily have non-uniform thickness, and the concentration of impurities implanted into the crystalline semiconductor layer can be easily controlled owing to this non-uniform thickness of the gate insulator. Thus, the low-impurity-concentration region can be easily formed in the crystalline semiconductor layer at the region covered with the thicker region of the gate insulator (region including the multilayer insulator).

Another aspect of the present invention is a method for producing the semiconductor device of the present invention. The production method comprises: patterning a resist on the gate insulator at a region covering a region where the low-impurity-concentration region is to be formed of the crystalline semiconductor layer; and adding impurities to the crystalline semiconductor layer through the gate insulator by the use of the resist as a mask. This method can enable easy formation of the low-impurity-concentration region in the crystalline semiconductor layer at the region masked by the resist with the number of steps less increased than the method utilizing the non-uniform thickness of the gate insulator.

Another aspect of the present invention is a method for producing the semiconductor device of the present invention. The production method comprises: patterning a first gate insulator on a region where the low-impurity-concentration region is to be formed of the crystalline semiconductor layer; forming a second gate insulator so as to cover the crystalline semiconductor layer and the first gate insulator; and adding impurities to the crystalline semiconductor layer through the first and second gate insulators. This method can enable easy formation of the gate insulator having non-uniform thickness. Thus, the concentration of the impurities added to the crystalline semiconductor layer can be easily controlled owing to the non-uniform thickness of the gate insulator. As a result, the low-impurity-concentration region can be easily formed in the crystalline semiconductor layer at the region covered with a thicker region of the gate insulator (region where the first and second gate insulators are stacked).

Each of these methods for producing the semiconductor device of the present invention is not especially limited as long as it essentially includes the aforementioned steps. The production methods may or may not include other steps.

Examples of the method for adding impurities to the crystalline semiconductor layer include ion implantation and ion doping. Preferably used is ion implantation because the amount of impurities and the depth profile of the added impurities are easily controlled therein.

Another aspect of the present invention is a display device provided with the semiconductor device of the present invention or the semiconductor device produced through the method for producing the semiconductor device of the present invention. In these cases, the semiconductor device which can reduce Iₒₙ defects is used in a display device. Thus, a display device with high reliability and low power consumption can be achieved at a high yield rate.

### EFFECT OF THE INVENTION

The semiconductor device and the display device of present invention provide the semiconductor device which can reduce Iₒₙ defects due to reduction in the on-current, the method for producing the same, and the display device.

### BEST MODE FOR CARRYING OUT THE INVENTION

The present invention will be mentioned in more detail referring to the drawings in the following embodiments, but is not limited to these embodiments.

### Embodiment 1

The semiconductor device of Embodiment 1 is described hereinbelow with the drawings.

FIG. 1 each are a schematic cross-sectional view showing the source/drain region and its vicinity of the TFT disposed on one semiconductor device of Embodiment 1; FIG. 1(a) shows a state of the region and its vicinity when impurities are ion-implanted at a high dose thereinto; and FIG. 1(b) shows a state of the region and its vicinity when the impurities are activated.

In FIGS. 1(a) and 1(b), difference in tones at the source/drain region 6 corresponds to difference in crystallinity. A darker portion indicates a region where the crystalline structure is further damaged and the crystallinity is lower. Also in the semiconductor device of Embodiment 1 shown in FIGS. 1(a) and 1(b), impurities are ion-implanted at a high dose so that the peak of the depth profile of the ion-implanted impurities is within the gate insulator, as in the conventional semiconductor device shown in FIGS. 8(a) and 8(b).

FIG. 2 is a schematic plan view showing the source/drain region and its vicinity of the TFT disposed on the semiconductor device of Embodiment 1.

As shown in FIG. 1(a), the semiconductor device of the present embodiment comprises the TFT including a crystalline semiconductor layer 2 having a channel region 5, the source/drain region 6, and a low-impurity-concentration region 7; a gate insulator 3; and a gate electrode 4, each stacked on a substrate 1 in this order from the side of the substrate 1. As shown in FIG. 1(b), the semiconductor device of the present embodiment further comprises a wiring 10 (the region defined by a dot line in FIG. 1(b)) connected to the source/drain region 6 via a contact hole. The channel region 5, the source/drain region 6, and the low-impurity-concentration region 7 are made from the same semiconductor layer, and are disposed adjacent to each other in the same plane.

The following will describe the production procedure of the semiconductor device of the present embodiment.

First, the crystalline semiconductor layer 2 having a thickness of 20 to 200 nm (preferably 30 to 70 nm) is formed on one main surface of the substrate 1 in an island-like state.

More specifically, the crystalline semiconductor layer 2 is formed by the steps of: forming an amorphous semiconductor film having an amorphous structure by sputtering, low-pressure chemical vapor deposition (LPCVD), or plasma CVD; crystallizing the amorphous semiconductor film with laser to provide a crystalline semiconductor film; and patterning the crystalline semiconductor film into a predetermined shape by photolithography. The material of the crystalline semiconductor layer 2 is not particularly limited, and it is preferably silicon. That is, the crystalline semiconductor layer 2 is preferably a polysilicon.

The crystallization for the crystalline semiconductor layer 2 may be performed by solid-phase growth in which a catalytic metal, such as nickel (Ni), is applied to the amorphous semiconductor film and then the film is heated. In this case, a continuous grain (CG) silicon film is formed as the crystalline semiconductor layer 2.

The material of the substrate 1 is not particularly limited. Examples of the substrate include glass substrates, quartz substrates, silicon substrates, metal substrates and stainless steel substrates with an insulator formed on the surface thereof, and plastic substrates having thermal resistance to processing temperatures. Particularly preferable are glass substrates which are used for display devices such as liquid crystal display devices.

A base layer may be formed between the substrate 1 and the crystalline semiconductor layer 2. Examples of the base layer include silicon-containing insulators (e.g. SiO₂, SiN, and SiNO). The base layer may have a monolayer structure of an insulator, or may have a multilayer structure of two or more insulators.

Next, the gate insulator 3 having a thickness of 20 to 200 nm (preferably 30 to 120 nm) is formed.

Preferably used as the gate insulator 3 is a silicon-containing insulator (e.g. SiO₂ film, SiN film, and SiNO film) formed by plasma CVD or sputtering. The gate insulator 3 may have a monolayer structure, or may have a multilayer structure including two or more insulators formed by insulating materials.

Here, impurities such as boron (B) may be ion-implanted at a low dose into the crystalline semiconductor layer 2 for the purpose of controlling the threshold voltage of the TFT.

Next, the gate electrode 4 having a thickness of 50 to 600 nm (preferably 100 to 500 nm) is formed.

More specifically, the gate electrode 4 is formed by the steps of forming a conducting film by sputtering; and patterning the conducting film into a predetermined shape by photolithography.

Preferable examples of the material of the gate electrode 4 include high melting point metals such as tantalum (Ta), tungsten (W), titanium (Ti), and molybdenum (Mo), and alloy materials and compound materials mainly containing these high melting point metals. Preferable examples of the compound mainly containing the high melting point metals include nitrides. The gate electrode 4 may have a multilayer structure of conductive layers containing these materials.

Next, the source/drain region 6 and the low-impurity-concentration region 7 are formed in the crystalline semiconductor layer 2 as shown in FIGS. 1(a) and 1(b) by the steps of patterning a photoresist (resist) 8 on the gate insulator 3 at a region covering the region where the low-impurity-concentration region 7 is to be formed; ion-implanting impurities 9 at a high dose into the crystalline semiconductor layer 2 through the gate insulator 3 with the photoresist 8 used as a mask; and activating the impurities.

More specifically, the impurities 9 such as phosphor (P) and boron (B) are ion-implanted at a dose of 5×10¹⁴ to 1×10¹⁶ cm⁻² (preferably 5×10¹⁴ to 5×10¹⁵ cm⁻²) and at an accelerating voltage as relatively low as 10 to 100 keV (preferably 20 to 80 keV). In the case that the impurities are ion-implanted under such conditions, the peak of the depth profile 12 of the ion-implanted impurities 9 is within the area including the inside of the gate insulator 3 and the side of the gate insulator 3 of the source/drain region 6. In this case, the crystalline structure of the source/drain region 6 at the region adjacent to the gate insulator 3 is most greatly damaged, and this region has the lowest crystallinity. In contrast, the crystalline structure of the source/drain region 6 at the region adjacent to the substrate 1 is less damaged, and this region has higher crystallinity.

The ion-implantation conditions may be changed so that the peak of the depth profile 12 of the ion-implanted impurities is outside the aforementioned area.

FIG. 18 is a cross-sectional view showing the source/drain region and its vicinity of the TFT disposed on the semiconductor device of Embodiment 1 in which the impurities are ion-implanted at a high dose under another condition. In FIG. 18, the symbols of the members not mentioned here are omitted.

In the case that the sheet resistance of the source/drain region 6 is not required to be greatly reduced, or in the case that it is advantageous to use, as the impurities 9, light ions (e.g. boron (B)) which less cause damages on the crystalline structure and insufficient crystal restoration in the source/drain region 6 upon activation, and thus to make the impurity concentration high in the source/drain region 6, the impurities 9 may be ion-implanted so that the peak of the depth profile 12 of the ion-implanted impurities 9 is within the area including the inside of the source/drain region 6 and the inside of the substrate 1.

On the other hand, in order to further reduce the sheet resistance of the source/drain region 6 and thus to more effectively avoid insufficient crystal restoration in the source/drain region 6 upon activation, the peak of the depth profile 12 of the ion-implanted impurities 9 is preferably set on the upper side of the source/drain region 6 as mentioned above.

Next, heating is performed at 350° C. to 720° C. (preferably 400° C. to 700° C.) for 4 to 240 minutes and thereby the impurities 9 implanted into the crystalline semiconductor layer 2 are activated and the crystalline structure of the crystalline semiconductor layer 2 is restored. Thus, the source/drain region 6 and the low-impurity-concentration region 7 are formed in the crystalline semiconductor layer 2.

The photoresist 8 is preferably removed after the ion implantation, but may be left (a resist residue may exist) on the gate insulator 3 at the region covering the low-impurity-concentration region 7. In the case that the resist residue exists on the gate insulator 3 at the region covering the low-impurity-concentration region 7, the region masked by the photoresist 8 on the crystalline semiconductor layer 2 is located. Thus, the properties such as a shape of the low-impurity-concentration region, the alignment accuracy, and the like factors can be easily tested and analyzed. In addition, the impurities 9 are not ion-implanted into the crystalline semiconductor region 2 at the region masked by the photoresist 8. Thus, in the case that the impurities for the purpose of controlling the threshold voltage of the TFT are not ion-implanted even at a low dose, the low-impurity-concentration region 7 formed with the photoresist 8 serves as a non-implanted region.

Then, an interlayer insulator and a wiring 10 are formed. As a result, the semiconductor device of the present embodiment is produced.

Preferably used as the material of the interlayer insulator is a silicon-containing insulator formed by plasma CVD or sputtering (e.g. SiO₂ film, SiN film, and SiNO film).

Preferable examples of the material of the wiring 10 include low-resistant metals such as aluminum (Al), copper (Cu), and silver (Ag), and alloy materials and compound materials mainly containing these low-resistant metals.

As mentioned above and shown in FIG. 8(b), the crystalline structure is restored mainly starting from the side of the substrate 1 of the source/drain region 6 where the crystalline structure has been less damaged in the conventional semiconductor device.

On the other hand, in the semiconductor device of the present embodiment, the crystalline structure is restored not only from the side of the substrate 1 but also from the side of the low-impurity-concentration region 7 in the source/drain region 6 upon activation as shown in FIG. 1(b) because the semiconductor device of the present embodiment is provided with the low-impurity-concentration region 7 as the starting point of the crystal restoration. Thus, the crystal restoration in the source/drain region 6 can be promoted. In particular, the crystalline structure is restored from the sides of the substrate 1 and the low-impurity-concentration region 7 at the region adjacent to the low-impurity-concentration region 7 in the source/drain region 6, that is, at the source/drain region 6 around the contacting portion 11 where the crystalline semiconductor layer 2 and the wiring 10 are in contact with each other in the semiconductor device of the present embodiment. Thus, the crystallinity of this region is greatly improved.

As a result, the sheet resistance of the source/drain region 6 is reduced and the contact resistance between the crystalline semiconductor layer 2 and the wiring 10 is reduced. Thus, contact failures are reduced. In addition, the reduction in the sheet resistance and the contact resistance of the source/drain region 6 causes reduction in the on-resistance of the semiconductor device. Thus, Iₒₙ defects due to reduction in the on-resistance are reduced.

As shown in FIGS. 1(b) and 2, the contacting portion 11 is disposed so as to partially overlap the low-impurity-concentration region 7 in the semiconductor device of the present embodiment. Thus, the source/drain region 6 where the crystalline structure has been restored adjacent to the low-impurity-concentration region 7 is surely disposed toward the contacting portion 11. As a result, the contact resistance is more surely reduced and contact failures and Iₒₙ defects are more surely reduced.

In the case that the contacting portion 11 partially overlaps the low-impurity-concentration region 7, the low-impurity-concentration region 7 can partially overlap at about 10 to 80% in area of the contacting portion 11.

The following will describe a modified example of the present embodiment.

The low-impurity-concentration region 7 may be formed through the use of the non-uniform thickness of the gate insulator 3.

FIGS. 13 each are a schematic view showing source/drain regions and their vicinities of a TFT disposed on another semiconductor device of Embodiment 1; FIG. 13(a) is a plan view; and FIG. 13(b) is an X1-Y1 line cross-sectional view in FIG. 13(a).

As shown in FIGS. 13(a) and 13(b), the gate insulator 3 may include two insulators of a first gate insulator 3a and a second gate insulator 3b stacked on the low-impurity-concentration region 7 and may include a single insulator of the second gate insulator 3b on the source/drain region 6. In other words, the gate insulator 3 may have non-uniform thickness.

The following will describe a method for forming the gate insulator 3 with non-uniform thickness, the source/drain region 6, and the low-impurity-concentration region 7.

First, the first insulator 3a having a thickness of 20 to 200 nm (preferably 20 to 80 nm, e.g. 50 nm) is formed so as to cover the crystalline semiconductor layer 2.

Next, a photoresist is patterned on the first gate insulator 3a at the regions where the low-impurity-concentration regions 7 are to be formed so as to mask the first gate insulator 3a. Then, the first gate insulator 3a is subjected to treatment such as wet etching with hydrogen fluoride (HF), and thereby the first gate insulator 3a at the regions where no mask has been formed is removed. Thus, openings (a region where the crystalline semiconductor layer 2 is exposed) are formed in the first gate insulator 3a at the regions including the contacting portions 11.

After the photoresist is removed, the second gate insulator 3b having a thickness of 20 to 200 nm (preferably 20 to 80 nm, e.g. 30 nm) is formed so as to cover the crystalline semiconductor layer 2 and the first gate insulator 3a. As a result, the gate insulator 3 is made to consist of the second gate insulator 3b at the opening of the first gate insulator 3a and is made to consist of the first gate insulator 3a and the second gate insulator 3b stacked at the regions except the opening, that is, at the regions where the low-impurity-concentration regions 7 are to be formed.

In the case that impurities are ion-implanted at a high dose into the crystalline semiconductor layer 2 through the gate insulator 3 with non-uniform thickness, the non-uniformity in thickness of the gate insulator 3 causes variations in the impurity concentration of the impurities ion-implanted into the crystalline semiconductor layer 2. In addition, the peaks of the depth profiles 12 of the ion-implanted impurities are at different positions. These features enable formation of the source/drain regions 6 and the low-impurity-concentration regions 7 in the crystalline semiconductor layer 2.

More specifically, as shown in FIG. 13(b), a smaller amount of impurities are ion-implanted into the crystalline semiconductor layer 2 at the regions covered with the thicker regions of the gate insulator 3 where the first gate insulator 3a and the second gate insulator 3b are stacked. Thus, the low-impurity-concentration regions 7 are formed at these regions. In contrast, a larger amount of impurities are ion-implanted into the crystalline semiconductor layer 2 at the regions covered with the thinner region of the gate insulator 3 consisting of the first gate insulator 3a only. Thus, the source/drain regions 6 are formed at this region after activation.

As mentioned here, the first gate insulator 3a may be formed on the crystalline semiconductor layer 2 at least at the regions where the low-impurity-concentration regions 7 are to be formed and at least except the regions where the source/drain regions 6 are to be formed.

In the modified embodiment shown in FIG. 13, the low-impurity-concentration regions are formed by use of the non-uniform thickness which is caused by stacking of the gate insulators; however, non-uniform thickness may be prepared on a single continuous gate insulator and the low-impurity-concentration region may be formed by use of this non-uniform thickness. Such non-uniform thickness of the continuous gate insulator may be prepared by formation of an oxide film through the local oxidation of silicon (LOCOS) process.

Alternatively, non-uniform quality may be prepared on a single continuous gate insulator, and the low-impurity-concentration regions may be formed by use of this non-uniform quality. Such non-uniform quality of the continuous gate insulator may be prepared as follows: selectively forming a photoresist on the gate insulator at the regions covering the regions where the low-impurity-concentration regions are to be formed; and ion-implanting impurities such as silicon (Si) ions and argon (Ar) ions into the gate insulator with the photoresist as a mask.

The low-impurity-concentration regions may be formed by use of both the non-uniform thickness and quality of the gate insulator. In this case, the amount of the impurities ion-implanted into the crystalline semiconductor layer is made much smaller at the regions where the low-impurity-concentration regions are to be formed. Thus, the crystalline structure is less damaged in the low-impurity-concentration regions and the crystal restoration in the source/drain regions is further promoted.

FIG. 3 is a schematic plan view showing the source/drain region and its vicinity of the TFT disposed on another semiconductor device of Embodiment 1.

As shown in FIG. 3, the low-impurity-concentration region 7 may be disposed along the perimeter of the contacting portion 11 except the channel-region side of the perimeter (the side of the gate electrode 4 in FIG. 3) in the plan view of the substrate. In this case, the crystal restoration in the source/drain region 6 around the contacting portion 11 is efficiently promoted. Thus, the contact resistance is reduced, and thereby contact failures and Iₒₙ defects are reduced.

As mentioned here, the low-impurity-concentration region 7 may have a shape with a depression (e.g. a U shape), and the depression may be formed along the perimeter of the contacting portion 11.

FIG. 4 is a schematic plan view showing the source/drain region and its vicinity of the TFT disposed on another semiconductor device of Embodiment 1.

The low-impurity-concentration region 7 may be disposed adjacent to the source/drain region 6 except a region between the contacting portion 11 and the channel region (the region covered with the gate electrode 4 in FIG. 4), and disposed along the current path between the contacting portion 11 and the channel region, that is, along the source/drain region 6 in the plan view of the substrate. In this case, the crystal restoration in the source/drain region 6 is promoted around the contacting portion 11, and the crystal restoration in the source/drain region is promoted also around the current path between the contacting portion 11 and the channel region. Thus, the sheet resistance of the source/drain region through which the current path runs between the contacting portion 11 and the channel region, is reduced and the on-resistance of the semiconductor device of the present embodiment is further reduced. As a result, Iₒₙ defects are further reduced.

As mentioned here, the low-impurity-concentration region 7 may be disposed along the region between the contacting portions 11 on opposite sides of the channel region in the plan view of the substrate.

In FIG. 4, the low-impurity-concentration region 7 is disposed along part of the perimeter of the contacting portion 11 in the plan view of the substrate; however, the position is not limited thereto, and the low-impurity-concentration region 7 may be disposed so as to partially overlap the contacting portion 11.

FIG. 5 is a schematic plan view showing the source/drain region and its vicinity of the TFT disposed on another semiconductor device of Embodiment 1.

As shown in FIG. 5, the low-impurity-concentration region 7 may be disposed along the current path between the contacting portion 11 and the channel region (the region corresponding to the gate electrode 4 in FIG. 5) and along the perimeter of the contacting portion 11 except the channel-region side of the perimeter. In this case, the crystal restoration in the source/drain region 6 is promoted around the current path between the contacting portion 11 and the channel region. Thus, the sheet resistance of the source/drain region 6 through which the current path runs between the contacting portion 11 and the channel region, is reduced. In addition, the crystal restoration in the source/drain region 6 is efficiently promoted around the contacting portion 11. Thus, the contact resistance is further reduced. As a result, the on-resistance of the semiconductor device is further reduced and Iₒₙ defects are further reduced. In addition, the contact resistance is further reduced and contact failures are further reduced.

As mentioned here, the low-impurity-concentration region 7 is disposed along the region between the contacting portions 11 on the opposite sides of the channel region and along the perimeter of each contacting portion 11 except the channel-region side of the perimeter.

FIG. 6 is a schematic plan view showing the source/drain region and its vicinity of the TFT disposed on another semiconductor device of Embodiment 1.

As shown in FIG. 6, the low-impurity-concentration region 7 may be disposed so as to overlap the perimeter of the contacting portion 11 except the channel-region side of the perimeter (the side of the gate electrode 4 in FIG. 6) in the plan view of the substrate. In this case, the source/drain region 6 with the crystalline structure restored is more surely disposed at the contacting portion 11 even though a misalignment has occurred upon formation of the contact hole for connection with the wiring 10. Thus, the contact resistance is more surely reduced and contact failures and Iₒₙ defects are more surely reduced even in the case that a producing apparatus used has poor alignment accuracy.

In FIG. 6, the low-impurity-concentration region 7 is disposed so as to overlap the whole perimeter of the contacting portion 11 except the channel-region side of the perimeter; however, the position is not limited thereto, and the low-impurity-concentration region 7 may be disposed so as to overlap a part of the perimeter of the contacting portion 11 except the channel-region side of the perimeter.

FIG. 7 is a schematic plan view showing the source/drain region and its vicinity of the TFT disposed on another semiconductor device of Embodiment 1.

As shown in FIG. 7, the low-impurity-concentration region 7 may be disposed so as to partially overlap the contacting portion 11, and an LDD region 22 may be disposed between the source/drain region 6 and the channel region (the region corresponding to the gate insulator 4 in FIG. 7) in the plan view of the substrate in the semiconductor device of the present invention. In this case, the source/drain region 6 adjacent to the low-impurity-concentration region 7 is surely disposed at the contacting portion 11 also in the TFT having the LDD region 22. Thus, the contact resistance is more surely reduced, and contact failures and Iₒₙ defects are more surely reduced in the TFT having the LDD region 22.

FIG. 12 is a schematic plan view showing the source/drain region and its vicinity of the TFT disposed on another semiconductor device of Embodiment 1.

As shown in FIG. 12, the LDD region 22 may be disposed between the source/drain region 6 and the channel region (the region corresponding to the gate electrode 4 in FIG. 12), and the low-impurity-concentration region 7 may be disposed along the current path between the contacting portion 11 and the channel region, that is, along the source/drain region 6 in the plan view of the substrate in the semiconductor device of the present invention. In this case, the crystal restoration in the source/drain region 6 is promoted around the contacting portion 11 and the crystal restoration in the source/drain region 6 is promoted around the current path between the contacting portion 11 and the channel region also in the TFT having the LDD region 22. Thus, the sheet resistance of the source/drain region 6 through which the current path runs between the contacting portion 11 and the channel region, is reduced and the on-resistance of the semiconductor device of the present embodiment is further reduced. As a result, Iₒₙ defects are further reduced.

As mentioned here, the LDD region 22 may be disposed between the source/drain region 6 and the channel region, and the low-impurity-concentration region 7 may be disposed along the region between the contacting portions 11 on the opposite sides of the channel region in the plan view of the substrate in the semiconductor device of the present embodiment.

The modes of the semiconductor device provided with the LDD region are not limited to those shown in FIGS. 7 and 12. For example, the semiconductor devices shown in FIGS. 3, 5, and 6 may be provided with the LDD region. The impurity concentration of the low-impurity-concentration region may be at the same level as or may be different from that of the LDD region.

As mentioned above, Embodiment 1 enables reduction in the on-resistance of the semiconductor device and reduction of Iₒₙ defects due to reduction in the on-current. The modes mentioned in the present embodiment may be employed in combination.

The present invention will be mentioned in more detail referring to the drawings in the following examples, but is not limited to these examples.

### EXAMPLE 1

FIG. 14 is a schematic plan view showing a TFT disposed on the semiconductor device of Example 1. The following will describe the method for producing the TFT disposed on the semiconductor device of Example 1.

First, an amorphous silicon layer was formed on a glass substrate, serving as the substrate, by LPCVD.

The amorphous silicon layer on the glass substrate was crystallized with laser. Then, the silicon layer was patterned. Thereby, a polysilicon layer having a thickness of 50 nm, serving as the crystalline semiconductor layer, was formed.

Next, a SiO₂ layer having a thickness of 30 nm, serving as the gate insulator, was formed by plasma CVD.

Next, a gate electrode 4 was formed, and then a photoresist was formed as a mask for ion implantation. The photoresist was patterned such that the regions where the source/drain regions 6 are to be formed in the crystalline semiconductor layer were located in openings (implantation regions) 13 of the photoresist and the regions where the low-impurity-concentration regions 7 are to be formed were masked.

Next, impurities were ion-implanted at a high dose into the polysilicon layer through the SiO₂ layer with the photoresist as a mask. Here, the implanted impurities were phosphor (P), and the ion implantation of the impurities at a high dose was performed under the following three conditions:

the standard condition (accelerating voltage: 20 keV, dose of impurity ions: 8×10¹⁴ cm⁻²);

the excessive condition 1 where the impurity concentration in the source/drain regions 6 was made about 4 times higher than that under the standard condition (after the ion implantation under the standard condition, ion implantation was further performed at an accelerating voltage of 30 keV and a dose of the impurity ions of 1.6×10¹⁵ cm⁻²); and the excessive condition 2 where the impurity concentration in the source/drain regions 6 was made about 6 times higher than that under the standard condition (after the ion implantation under the standard condition, ion implantation was further performed at an accelerating voltage of 45 keV and a dose of the impurity ions of 1.6×10¹⁵ cm⁻²).

Thus, the low-impurity-concentration regions 7 were formed in the polysilicon layer at the regions masked by the photoresist.

Heating was performed at 550° C. for 240 minutes, and thereby the impurities implanted into the polysilicon layer were activated and the crystalline structure of the polysilicon layer was restored. Thereby, the source/drain regions 6 were formed. The low-impurity-concentration regions 7 were disposed so as to partially overlap the contacting portions 11, and along the current path between the contacting portions 11 and the channel region (the region corresponding to the gate insulator 4 in FIG. 14), that is, along the source/drain regions 6.

A TFT 100a was produced by the above steps.

The thus produced TFT 100a disposed on the semiconductor device of Example 1 was evaluated for the Vg (gate voltage)-Id (drain current) characteristics.

FIGS. 15 each are a graph showing a Vg-Id characteristic of the TFT disposed on the semiconductor device of Example 1; FIG. 15(a) shows the characteristic under the standard condition; FIG. 15(b) shows the characteristic under the excessive implantation condition 1; and FIG. 15(c) shows the characteristic under the excessive implantation condition 2.

In FIG. 15, the symbol “E” on the vertical axis for the drain currents means the power of 10. For example, 1E-03 corresponds to 1×10⁻³.

As shown in FIGS. 15(a) to 15(c), the Vg-Id characteristics of the TFT 100a show that the on-currents did not greatly decrease at the saturation regions and the linear regions, and the curves were less dispersed even though the impurities were excessively ion-implanted and thus the impurity concentration is made high in the source/drain regions 6. This result makes it clear that the crystalline structure is sufficiently restored in the source/drain regions 6 of the TFT 100a having the low-impurity-concentration regions 7.

### COMPARATIVE EXAMPLE 1

FIG. 16 is a schematic plan view showing a TFT disposed on the semiconductor device of Comparative Example 1. The following will describe the method for producing the TFT for the semiconductor device of Comparative Example 1.

In the production of a TFT 100b disposed on the semiconductor device of Comparative Example 1, the photoresist was not formed, the impurities were ion-implanted at a high dose such that the whole crystalline semiconductor layer was within the implantation region 13, and the crystalline semiconductor layer except the region masked by the gate electrode 4 (including the region to be the contacting portion 11) was made to be the source/drain region 6. In other words, the TFT 100b had no low-impurity-concentration region. The other steps for producing the TFT 100b were the same as those for the TFT 100a in Example 1.

The thus produced TFT 100b of the semiconductor device of Comparative Example 1 was evaluated for the Vg-Id characteristics.

FIGS. 17 each are a graph showing a Vg-Id characteristic of the TFT disposed on the semiconductor device of Comparative Example 1; FIG. 17(a) shows the characteristic under the standard condition; FIG. 17(b) shows the characteristic under the excessive implantation condition 1; and FIG. 17(c) shows the characteristic under the excessive implantation condition 2.

In FIG. 17, the symbol “E” on the vertical axis for the drain currents means the power of 10. For example, 1E-03 corresponds to 1×10⁻³.

As shown in FIGS. 17(a) to 17(c), the Vg-Id characteristics of the TFT 100b show that the curves were more dispersed than in the characteristics of the TFT 100a under the standard condition. The more excessively the impurities were ion-implanted, the more the curves were dispersed at the saturation and linear regions and the lower the Vg is at which the on-currents reached the limit. This is presumably because, in the case that an excessive amount of the impurities are ion-implanted into the crystalline semiconductor layer of the TFT having no low-impurity-concentration region, the crystalline structure is insufficiently restored in the source/drain region and the sheet resistance of the source/drain region and the contact resistance between the source/drain region and the wiring increase, and thereby the on-resistance increases.

As mentioned above, Example 1 proves that the effect of promoting the crystal restoration in the source/drain regions 6 by the low-impurity-concentration regions 7 is effective in improvement of the characteristics of the TFT disposed on the semiconductor device. As in Example 1, the low-impurity-concentration regions 7, which are disposed so as to partially overlap the contacting portions 11 and along the current path between the contacting portions 11 and the channel region, that is, along the source/drain regions 6, more effectively improves the characteristics of the TFT disposed on the semiconductor device.

The present application claims priority to Patent Application No. 2008-92871 filed in Japan on Mar. 31, 2008 under the Paris Convention and provisions of national law in a designated State. The entire contents of which are hereby incorporated by reference.

### BRIEF DESCRIPTION OF THE DRAWINGS

FIGS. 1 each are a schematic cross-sectional view showing a source/drain region and its vicinity of a TFT disposed on one semiconductor device of Embodiment 1; FIG. 1(a) shows a state of the region and its vicinity when impurities are ion-implanted at a high dose thereinto; and FIG. 1(b) shows a state of the region and its vicinity when the impurities are activated.

FIG. 2 is a schematic plan view showing the source/drain region and its vicinity of the TFT disposed on the semiconductor device of Embodiment 1.

FIG. 3 is a schematic plan view showing the source/drain region and its vicinity of the TFT disposed on another semiconductor device of Embodiment 1.

FIG. 4 is a schematic plan view showing the source/drain region and its vicinity of the TFT disposed on another semiconductor device of Embodiment 1.

FIG. 5 is a schematic plan view showing the source/drain region and its vicinity of the TFT disposed on another semiconductor device of Embodiment 1.

FIG. 6 is a schematic plan view showing the source/drain region and its vicinity of the TFT disposed on another semiconductor device of Embodiment 1.

FIG. 7 is a schematic plan view showing the source/drain region and its vicinity of the TFT disposed on another semiconductor device of Embodiment 1.

FIGS. 8 each are a schematic cross-sectional view showing the source/drain region and its vicinity of the TFT disposed on a conventional semiconductor device; FIG. 8(a) shows a state of the region and its vicinity when impurities are ion-implanted at a high dose thereinto; and FIG. 8(b) shows a state of the region and its vicinity when the impurities are activated.

FIG. 9(a) is an optical micrograph of polysilicon before activation; and FIG. 9(b) is a graph showing the Raman spectrum of the polysilicon before activation.

FIG. 10(a) is an optical micrograph of polysilicon after activation; and FIG. 10(b) is a graph showing the Raman spectrum of the polysilicon after activation.

FIG. 11(a) is an optical micrograph of amorphous silicon; and FIG. 11(b) is a graph showing the Raman spectrum of the amorphous silicon.

FIG. 12 is a schematic plan view showing the source/drain region and its vicinity of the TFT disposed on another semiconductor device of Embodiment 1.

FIGS. 13 each are a schematic view showing the source/drain region and its vicinity of the TFT disposed on another semiconductor device of Embodiment 1; FIG. 13(a) is a plan view; and FIG. 13(b) is an X1-Y1 line cross-sectional view in FIG. 13(a).

FIG. 14 is a schematic plan view showing a TFT disposed on the semiconductor device of Example 1.

FIGS. 15 each are a graph showing a Vg-Id characteristic of the TFT disposed on the semiconductor device of Example 1; FIG. 15(a) shows the characteristic under the standard condition; FIG. 15(b) shows the characteristic under the excessive implantation condition 1; and FIG. 15(c) shows the characteristic under the excessive implantation condition 2.

FIG. 16 is a schematic plan view showing the TFT disposed on the semiconductor device of Comparative Example 1.

FIGS. 17 each are a graph showing a Vg-Id characteristic of the TFT disposed on the semiconductor device of Comparative Example 1; FIG. 17(a) shows the characteristic under the standard condition; FIG. 17(b) shows the characteristic under the excessive implantation condition 1; and FIG. 17(c) shows the characteristic under the excessive implantation condition 2.

FIG. 18 is a cross-sectional view showing the source/drain region and its vicinity of the TFT disposed on one semiconductor device of Embodiment 1 with impurities ion-implanted at a high dose under another condition.

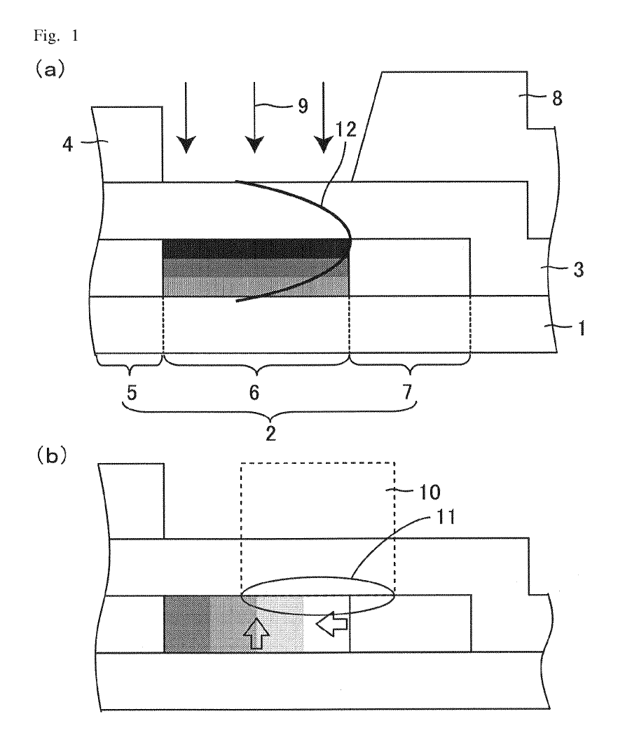

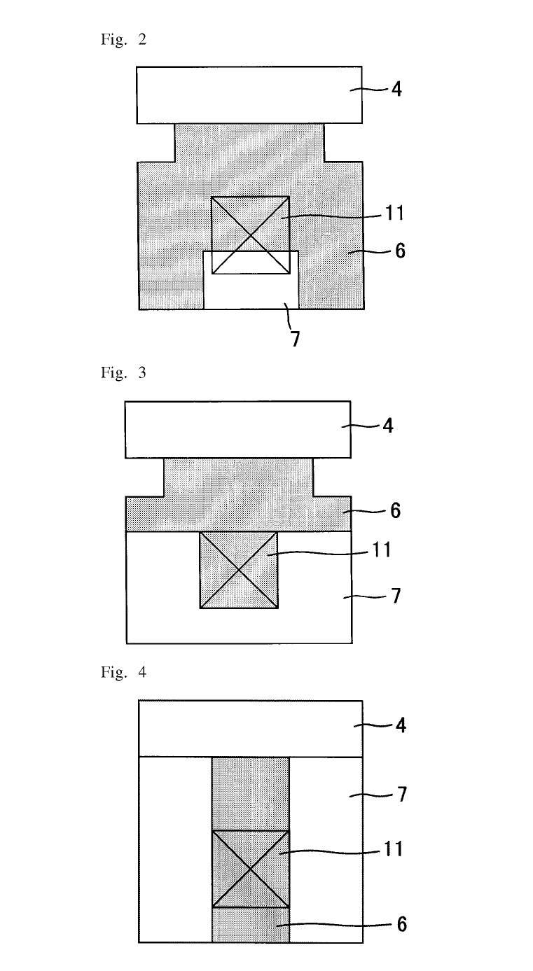

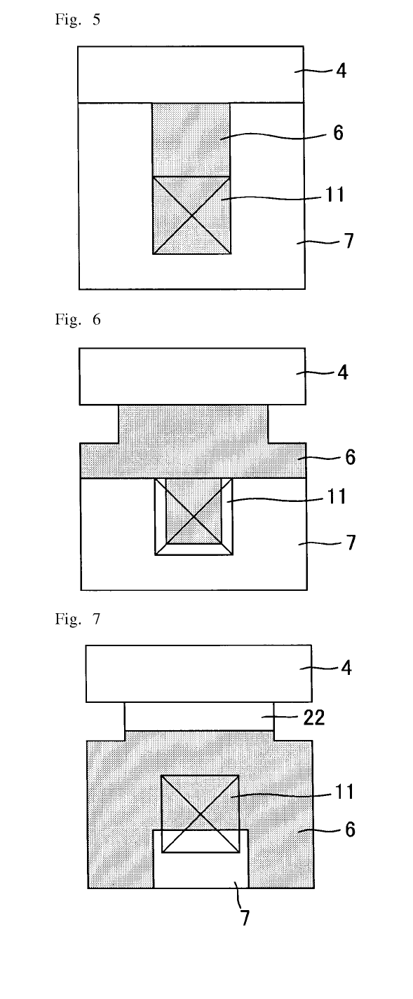

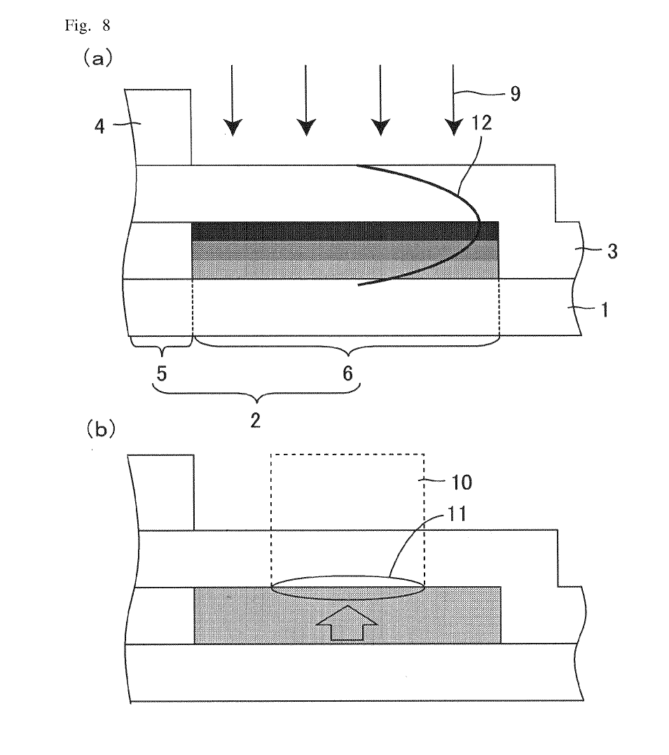

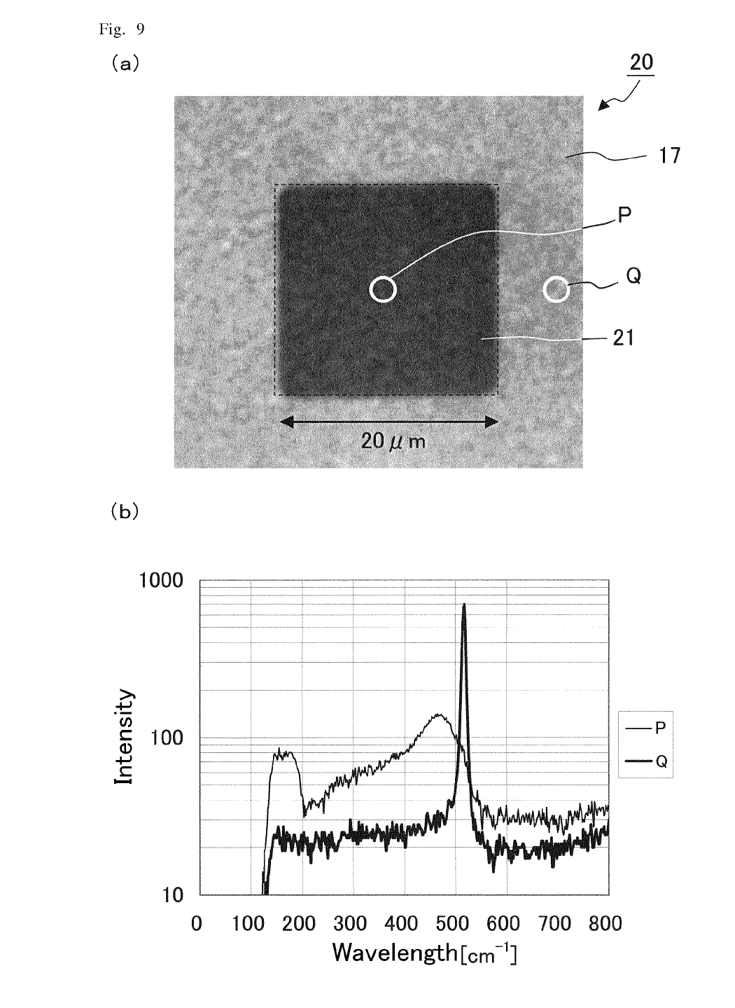

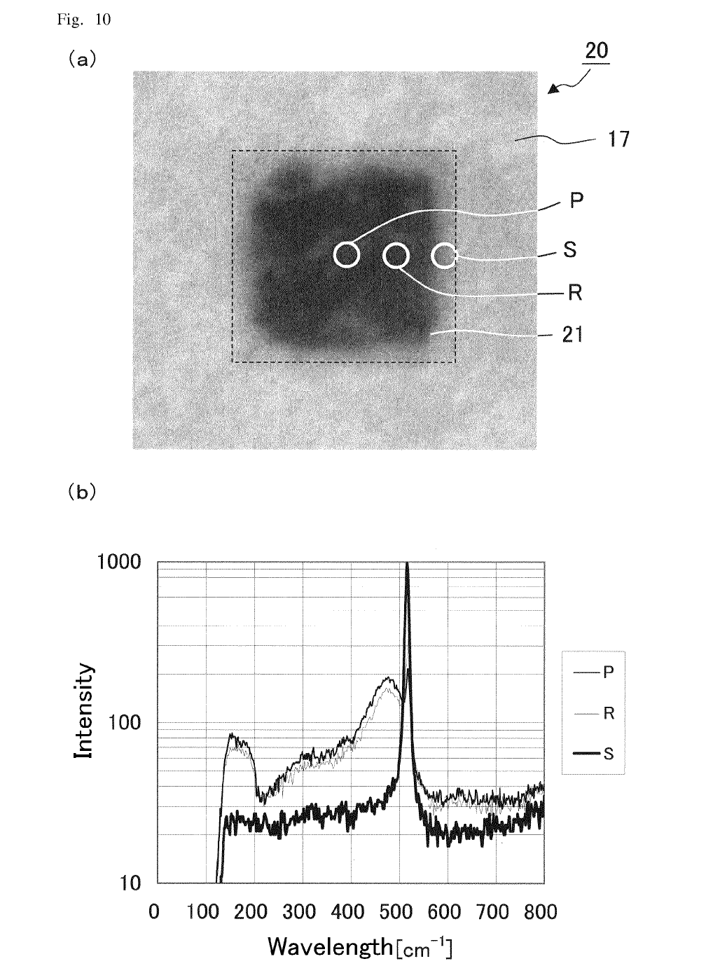

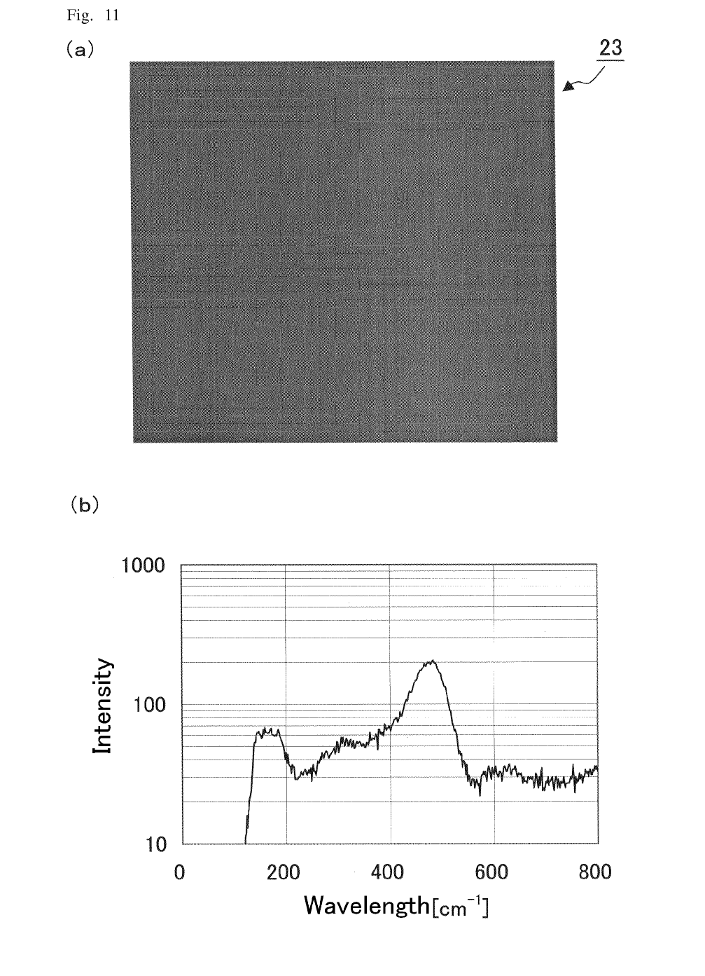

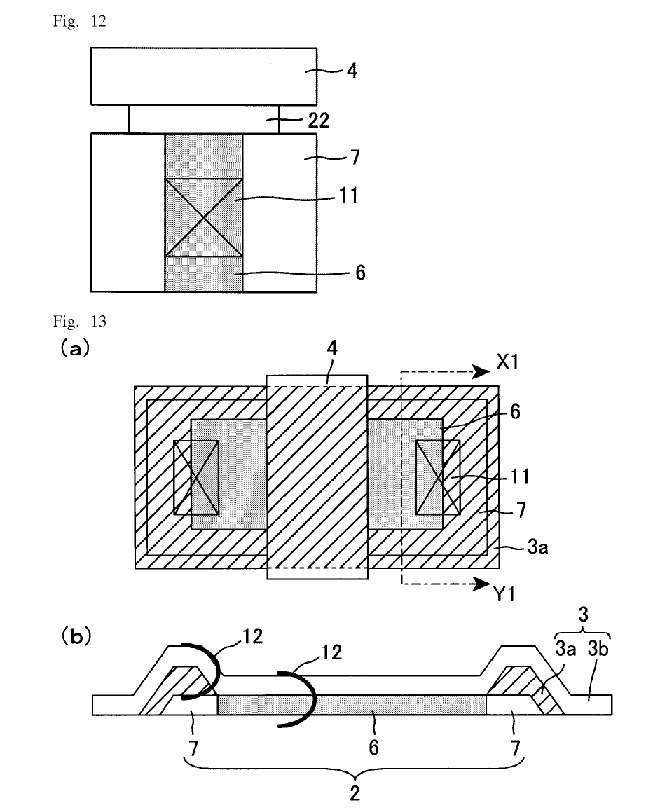

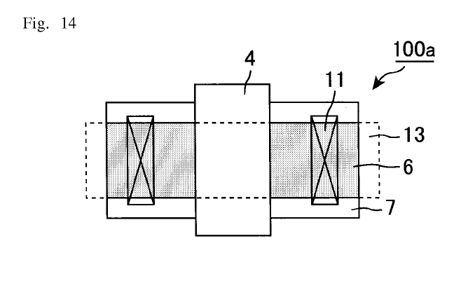

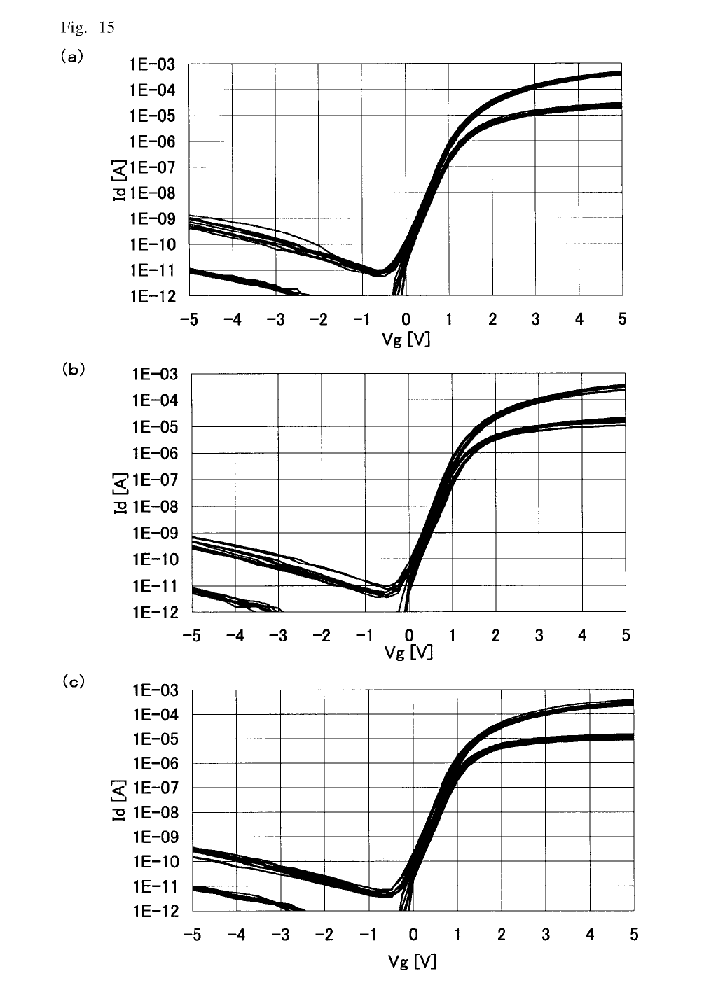

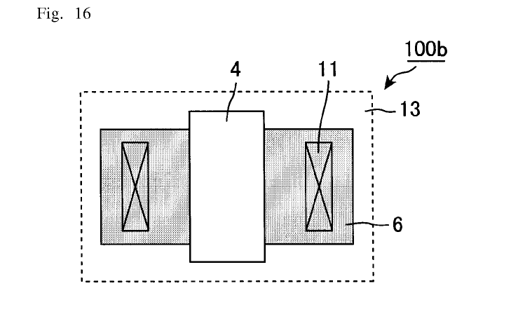

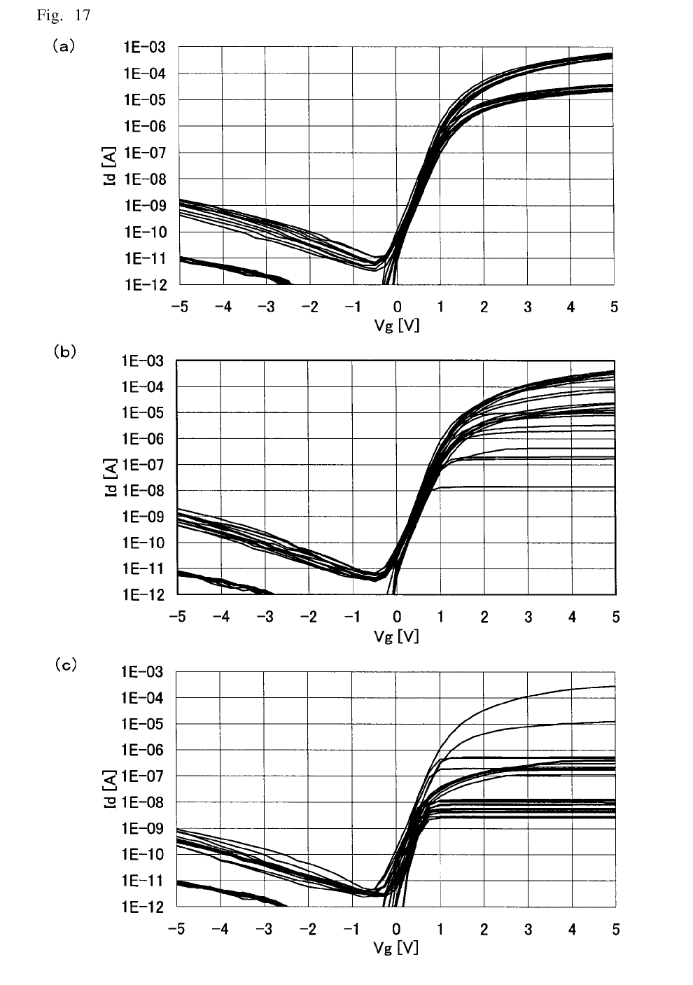

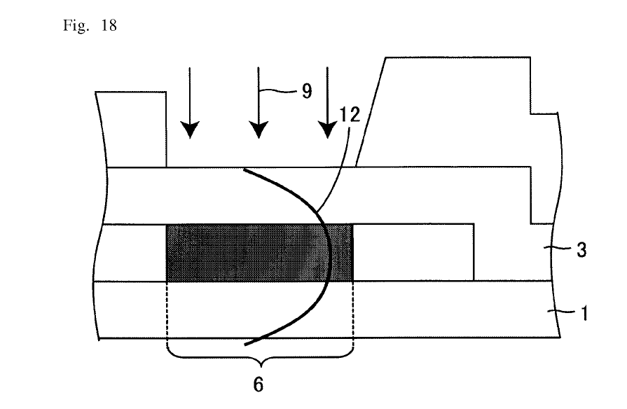

### EXPLANATION OF SYMBOLS

1: Substrate

2: Crystalline semiconductor device

3: Gate insulator

3a: First gate insulator

3b: Second gate insulator

4: Gate electrode

5: Channel region

6: Source/drain region

7, 17: Low-impurity-concentration region (non-implantation region)

8: Photoresist (resist)

9: Impurities

10: Wiring

11: Contacting portion

12: Depth profile

13: Opening of photoresist (implantation region)

20: Polysilicon

21: Ion-implantation region

22: LDD region

23: Amorphous silicon

100a, 100b: TFT

1. A semiconductor device comprising:
a substrate;
a thin film transistor including a crystalline semiconductor layer which has a channel region and a source/drain region; and
a wiring connected to the source/drain region, the thin film transistor and the wiring being disposed on the substrate,
the crystalline semiconductor layer further having a low-impurity-concentration region which has a lower impurity concentration than that of the source/drain region and a contacting portion contacting with the wiring, and
the low-impurity-concentration region being disposed adjacent to the source/drain region except a region on a channel-region side of the source/drain region.

2. The semiconductor device according to claim 1,
wherein the low-impurity-concentration region is disposed on the same plane of the source/drain region.

3. The semiconductor device according to claim 2,
wherein the contacting portion partially overlaps the low-impurity-concentration region.

4. The semiconductor device according to claim 2,
wherein the low-impurity-concentration region is disposed along a perimeter of the contacting portion except a channel-region side of the perimeter in the plan view of the substrate.

5. The semiconductor device according to claim 2,
wherein the low-impurity-concentration region is disposed along a current path between the contacting portion and the channel region in the plan view of the substrate.

6. The semiconductor device according to claim 2,
wherein the low-impurity-concentration region is disposed along a current path between the contacting portion and the channel region and along a perimeter of the contacting portion except the channel-region side of the perimeter in the plan view of the substrate.

7. The semiconductor device according to claim 2, further comprising:
a gate insulator in the thin film transistor; and
a resist disposed on the gate insulator and covering the low-impurity-concentration region.

8. The semiconductor device according to claim 2,
wherein the thin film transistor further includes a gate insulator,
a region covering the low-impurity-concentration region and a region covering the source/drain region are integrated in the gate insulator, and
at least one of the thickness and quality of the gate insulator at the region covering the low-impurity-concentration is different from those at the region covering the source/drain region.

9. The semiconductor device according to claim 2,
wherein the thin film transistor further includes a gate insulator, and
the gate insulator includes a multilayer insulator at a region covering the low-impurity-concentration region.

10. A method for producing the semiconductor device according to claim 2, the method comprising:
patterning a resist on a gate insulator at a region covering a region where the low-impurity-concentration region is to be formed of the crystalline semiconductor layer; and
adding impurities to the crystalline semiconductor layer through the gate insulator by the use of the resist as a mask.

11. A method for producing the semiconductor device according to claim 2, the method comprising:
patterning a first gate insulator on a region where the low-impurity-concentration region is to be formed of the crystalline semiconductor layer;
forming a second gate insulator so as to cover the crystalline semiconductor layer and the first gate insulator; and
adding impurities to the crystalline semiconductor layer through the first and second gate insulators.

12. A display device comprising
the semiconductor device according to claim 1.

13. A display device comprising
a semiconductor device produced by the method for producing a semiconductor device according to claim 10.
